(19) United States
(12) Patent Application Publication
(10) Pub. No.: US 2026/0059653 A1
(43) Pub. Date: Feb. 26, 2026

(54) ELECTRONIC DEVICE INCLUDING PRINTED CIRCUIT BOARD

(71) Applicant: Samsung Electronics Co., Ltd., Suwon-si (KR)

(72) Inventors: Jongmin KIM, Suwon-si (KR); Eunbae KWON, Suwon-si (KR); Sanguk KIM, Suwon-si (KR); Hyoseok NA, Suwon-si (KR); Kyonghwan CHO, Suwon-si (KR)

(21) Appl. No.: 19/303,855

(22) Filed: Aug. 19, 2025

Related U.S. Application Data
(63) Continuation of application No. PCT/KR2025/007205, filed on May 27, 2025.

(30) Foreign Application Priority Data
Aug. 24, 2024 (KR) 10-2024-0113897
Oct. 8, 2024 (KR) 10-2024-0137171

(51) Int. Cl. H05K 1/02; H05K 1/14; H05K 7/14; H05K 7/18

(52) U.S. Cl. CPC H05K 1/025; H05K 1/0215; H05K 1/148; H05K 7/1417; H05K 7/186; H05K 2201/09354; H05K 2201/10098

(57) ABSTRACT

An electronic device includes an antenna radiator, a printed circuit board, an antenna contact, and impedance circuitry. The printed circuit board includes a first PCB portion including at least one ground layer electrically connected to a ground of the electronic device, a second PCB portion electrically insulated from the at least one ground layer, an opening defined by a lateral side of an edge portion of the first PCB portion and a lateral side of an edge portion of the second PCB portion, and a conductive material, plated on the lateral side of the edge portion of the first PCB portion, and electrically connected to the at least one ground layer. The impedance circuitry is electrically connected to the at least one ground layer through the conductive material.

### CROSS-REFERENCE TO RELATED APPLICATIONS

This application is a continuation of International Application No. PCT/KR2025/007205 designating the United States, filed on May 27, 2025, in the Korean Intellectual Property Receiving Office and claiming priority to Korean Patent Application Nos. 10-2024-0113897, filed on Aug. 24, 2024, and 10-2024-0137171, filed on Oct. 8, 2024, in the Korean Intellectual Property Office, the disclosures of each of which are incorporated by reference herein in their entireties.

### BACKGROUND

### Field

The disclosure relates to an electronic device including a printed circuit board.

### Description of Related Art

An electronic device may include an antenna for communication with an external electronic device. The antenna may include a conductive portion forming at least a portion of a periphery portion of the electronic device. The conductive portion may be configured to function as an antenna radiator for transmitting or receiving a signal. The antenna radiator may be electrically connected to wireless communication circuitry through a printed circuit board. An electronic component (e.g., a matching circuit) for the antenna may be disposed on the printed circuit board.

The above-described information may be provided as a related art for the purpose of helping to understand the present disclosure. No assertion or determination is made as to whether any of the above-described information may be applied as a prior art related to the present disclosure.

### SUMMARY

An electronic device is disclosed. The electronic device may comprise an antenna radiator. The electronic device may comprise a printed circuit board (PCB). The printed circuit board may comprise a first PCB portion including a plurality of layers. The plurality of layers of the first PCB portion may include at least one ground layer electrically connected to a ground of the electronic device. The printed circuit board may comprise a second PCB portion, disposed alongside the first PCB portion, and including a plurality of layers. The second PCB portion may be electrically insulated from the at least one ground layer of the first PCB portion. The printed circuit board may comprise an opening defined by both a lateral side of an edge portion of the first PCB portion and a lateral side of an edge portion of the second PCB portion. The printed circuit board may comprise a conductive material, plated on the lateral side of the edge portion of the first PCB portion, and electrically connected to the at least one ground layer of the first PCB portion. The electronic device may comprise an antenna contact, electrically connected to the antenna radiator, and mounted on the second PCB portion. The electronic device may comprise impedance circuitry, mounted on a region of the first PCB portion that comprises at least a portion of the edge portion of the first PCB portion, and electrically connected to the antenna contact. The impedance circuitry may be also electrically connected to the at least one ground layer of the first PCB portion through the conductive material.

An electronic device is disclosed. The electronic device may comprise wireless communication circuitry. The electronic device may comprise an antenna radiator configured to transmit and/or receive radio frequency (RF) signals. The electronic device may comprise a PCB configured to electrically connect the wireless communication circuitry and the antenna radiator. The electronic device may comprise a bracket, supporting the PCB, and configured to function as a ground of the electronic device. The PCB may include a first PCB portion including at least one ground layer electrically connected to the bracket, a second PCB portion, disposed alongside the first PCB portion, electrically insulated from the at least one ground layer of the first PCB, and on which an antenna contact electrically connected to the antenna radiator is disposed, an opening defined by both a lateral side of an edge portion of the first PCB portion and a lateral side of an edge portion of the second PCB portion, and a conductive material, plated on the lateral side of the edge portion of the first PCB portion, electrically connected to the at least one ground layer of the first PCB portion. A thickness of the conductive material may substantially correspond to a thickness of the first PCB portion of the PCB.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a diagram illustrating an example electronic device according to various embodiments;

FIG. 3 is an exploded perspective view of an electronic device according to various embodiments;

FIG. 4 is a block diagram illustrating an example configuration of an electronic device according to various embodiments;

FIG. 5 is a partial exploded perspective view illustrating a portion of an electronic device according to various embodiments;

FIG. 6 is a diagram illustrating a plan view of a printed circuit board according to various embodiments;

FIG. 7 is a partial perspective view of a printed circuit board according to various embodiments;

FIG. 8 is a cross-sectional view of a printed circuit board of FIG. 6 taken along line A-A′ according to various embodiments;

FIG. 9 is a diagram illustrating a portion of a printed circuit board according to a comparative example;

FIGS. 10 and 11 are diagrams illustrating a portion of a printed circuit board including an opening according to various embodiments;

FIG. 12 is a diagram illustrating a plan view of a printed circuit board according to various embodiments;

FIG. 13 is a diagram illustrating an example of an X region of FIG. 12 in a printed circuit board according to various embodiments;

FIG. 14 is a diagram illustrating an example of a Y region of FIG. 12 in a printed circuit board according to various embodiments;

FIG. 15 is a flowchart illustrating an example process of forming a conductive material of a printed circuit board according to various embodiments; and

FIGS. 16, 17, 18, 19, and 20 are diagrams illustrating various processes of forming an opening according to various embodiments.

### DETAILED DESCRIPTION

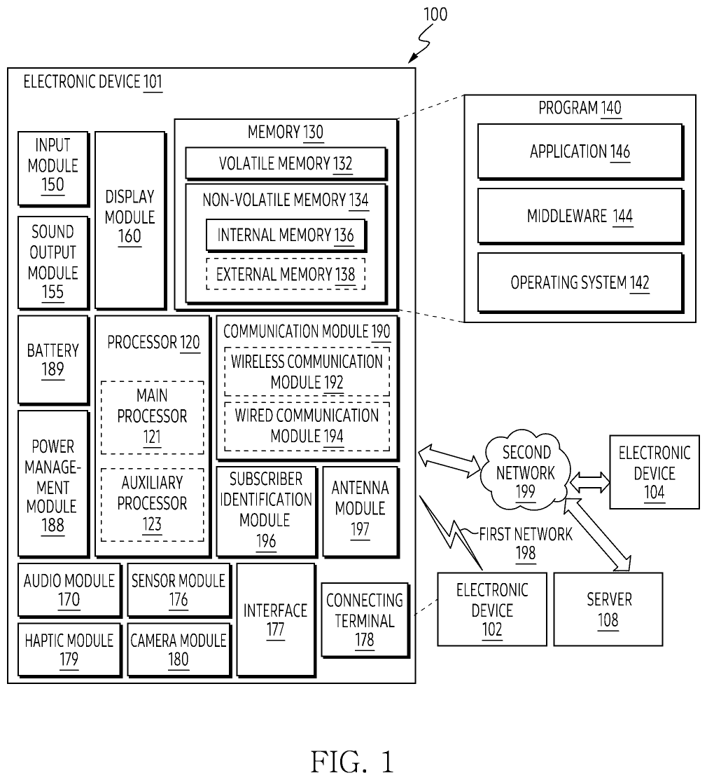

FIG. 1 is a block diagram illustrating an example electronic device in a network environment according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

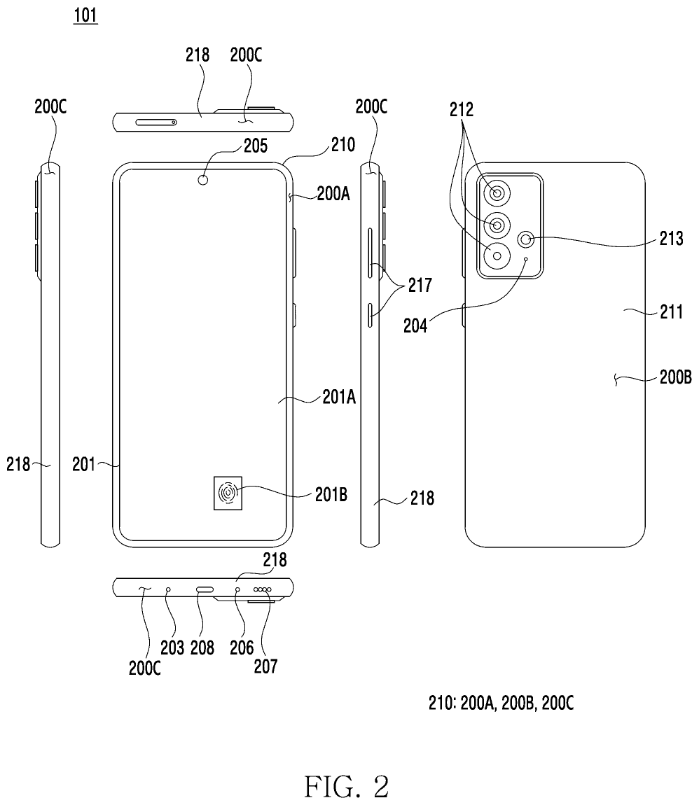

FIG. 2 is a diagram illustrating an example electronic device according to various embodiments.

Referring to FIG. 2, an electronic device 101 according to an embodiment may include a housing 210 forming an exterior of the electronic device 101. For example, the housing 210 may include a first surface (or a front surface) 200A, a second surface (or a rear surface) 200B, and a third surface (or a lateral side) 200C surrounding a space between the first surface 200A and the second surface 200B.

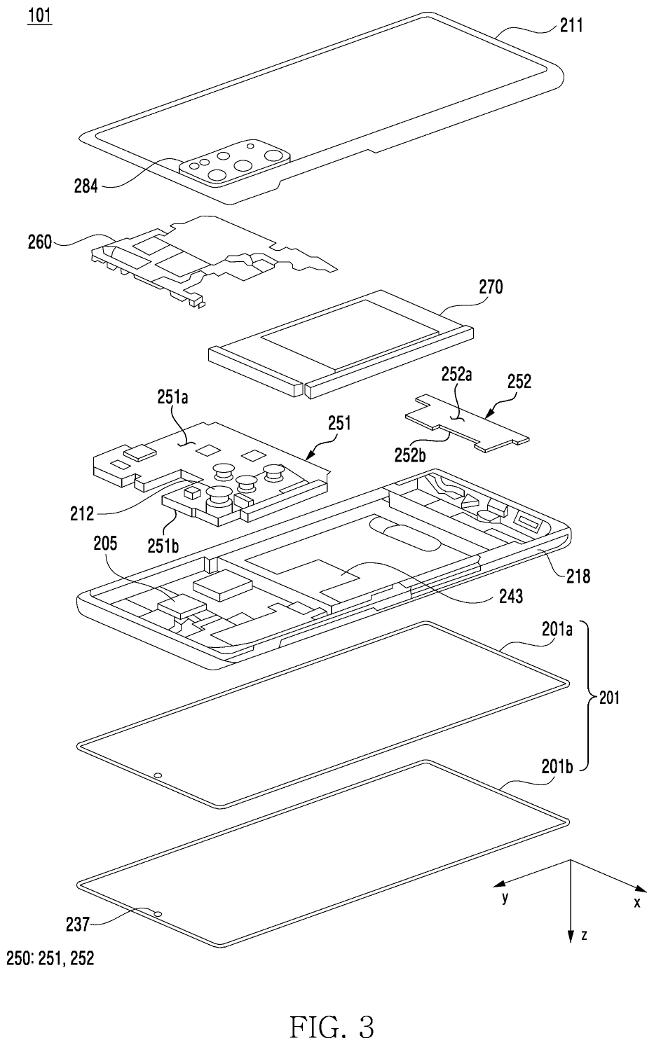

According to an embodiment, the electronic device 101 may include a display (e.g., the display module 160 of FIG. 1). A display 201 may include a substantially transparent window (e.g., a window 201b of FIG. 3). The window 201b may form at least a portion of the first surface 200A. For example, the window 201b may include a glass plate or a polymer plate that include various coating layers, but is not limited thereto.

According to an embodiment, the electronic device 101 may include a substantially opaque cover plate 211. According to an embodiment, the cover plate 211 may form at least a portion of the second surface 200B. According to an embodiment, the cover plate 211 may be formed of coated or colored glass, ceramic, polymer, metal (e.g., aluminum, stainless steel (STS), or magnesium), or a combination of at least two of the above materials.

According to an embodiment, the electronic device 101 may include a frame 218. The frame 218 may form at least a portion of the third surface 200C of the electronic device 101 by being coupled to the window 201b and/or the cover plate 211. For example, the frame 218 may form the entire third surface 200C of the electronic device 101. For example, the frame 218 may form the third surface 200C of the electronic device 101 together with the window 201b and/or the cover plate 211.

According to an embodiment, the electronic device 101 may include at least one of the display 201, audio modules 203, 204, and 207, a sensor module (not illustrated), camera modules 205, 212, and 213, a key input device 217, a light emitting element (not illustrated), and/or a connector hole 208. According to an embodiment, the electronic device 101 may omit at least one of the components (e.g., the key input device 217 or the light emitting element (not illustrated)), or may additionally include another component.

According to an embodiment, at least a portion of the display 201 may be visible through the window 201b forming the first surface 200A. According to an embodiment, the display 201 may include a display panel (e.g., the display panel 201a of FIG. 3) disposed on a rear surface of the window 201b.

According to an embodiment, the display 201 may include a display region 201A. According to an embodiment, the display 201 may provide visual information to a user through the display region 201A.

According to an embodiment, the display region 201A may include a sensing region 201B configured to obtain biometric information of a user. Herein, “the display region 201A includes the sensing region 201B” may be understood as the sensing region 201B being at least partially overlapped with the display region 201A. For example, the sensing region 201B may refer, for example, to a region capable of displaying visual information by the display 201 like another region of the display region 201A and additionally obtaining the biometric information (e.g., a fingerprint) of the user. According to an embodiment, the sensing region 201B may be formed in the key input device 217.

According to an embodiment, the display 201 may include a region in which the first camera module 205 (e.g., the camera module 180 of FIG. 1) is located. According to an embodiment, an opening may be formed in the region of the display 201, and the first camera module 205 (e.g., a punch hole camera) may be at least partially disposed in the opening to face the first surface 200A. For example, the display region 201A may surround at least a portion of a periphery of the opening. According to an embodiment, the first camera module 205 (e.g., an under display camera (UDC)) may be disposed under the display 201 to overlap the region of the display 201. For example, the display 201 may provide visual information to the user through the region, and additionally, the first camera module 205 may obtain an image corresponding to a direction toward the first surface 200A through the region of the display 201.

According to an embodiment, the display 201 may be coupled or disposed adjacent to a touch sensing circuit, a pressure sensor capable of measuring intensity (pressure) of a touch, and/or a digitizer that detects a magnetic field type stylus pen.

According to an embodiment, the audio modules 203, 204, and 207 (e.g., the audio module 170 of FIG. 1) may include microphone holes 203 and 204 and/or a speaker hole 207.

According to an embodiment, the microphone holes 203 and 204 may include a first microphone hole 203 formed in a partial region of the third surface 200C and/or a second microphone hole 204 formed in a partial region of the second surface 200B. A microphone (not illustrated) for obtaining external sound may be disposed in the microphone holes 203 and 204. The microphone may include a plurality of microphones to sense a direction of sound.

According to an embodiment, the second microphone hole 204 formed in the partial region of the second surface 200B may be disposed adjacent to the camera modules 205, 212, and 213. For example, the second microphone hole 204 may obtain sound according to an operation of the camera modules 205, 212, and 213. However, the disclosure is not limited thereto.

According to an embodiment, the speaker hole 207 may include an external speaker hole 207 and a call receiver hole (not illustrated). The external speaker hole 207 may be formed on a portion of the third surface 200C of the electronic device 101. According to an embodiment, the external speaker hole 207 and the microphone hole 203 may be implemented as one hole. Although not illustrated, the call receiver hole (not illustrated) may be formed on another portion of the third surface 200C. For example, the call receiver hole may be formed on an opposite side of the external speaker hole 207 on the third surface 200C. For example, based on the illustration of FIG. 2, the external speaker hole 207 may be formed on the third surface 200C corresponding to a lower end of the electronic device 101, and the call receiver hole may be formed on the third surface 200C corresponding to an upper end of the electronic device 101. However, the disclosure is not limited thereto, and according to an embodiment, the call receiver hole may be formed at a position other than the third surface 200C. For example, the call receiver hole may be formed by a separated space between the display 201 and the frame 218.

According to an embodiment, the electronic device 101 may include at least one speaker (not illustrated) configured to output sound to the outside of the housing 210 through the external speaker hole 207 and/or the call receiver hole (not illustrated).

According to an embodiment, the sensor module (not illustrated) (e.g., the sensor module 176 of FIG. 1) may generate an electrical signal or a data value corresponding to an operating state inside the electronic device 101 or an external environmental state. For example, the sensor module may include at least one of a proximity sensor, an HRM sensor, a fingerprint sensor, a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor.

According to an embodiment, the camera modules 205, 212, and 213 (e.g., the camera module 180 of FIG. 1) may include a first camera module 205 disposed to face the first surface 200A of the electronic device 101, a second camera module 212 and a flash 213 disposed to face the second surface 200B.

According to an embodiment, the second camera module 212 may include a plurality of cameras (e.g., a dual camera, a triple camera, or a quad camera). However, the second camera module 212 is not necessarily limited to including the plurality of cameras, and may include one camera.

According to an embodiment, the first camera module 205 and the second camera module 212 may include one or more lenses, an image sensor, and/or an image signal processor.

According to an embodiment, the flash 213 may, for example, include a light emitting diode or a xenon lamp. According to an embodiment, two or more lenses (e.g., an infrared camera, a wide-angle and telephoto lens) and image sensors may be disposed on one side of the electronic device 101.

According to an embodiment, the key input device 217 (e.g., the input module 150 of FIG. 1) may be disposed on the third surface 200C of the electronic device 101. According to an embodiment, the electronic device 101 may not include a portion or all of the key input device 217, and the excluded key input device 217 may be implemented in another form, such as a soft key, on the display 201.

According to an embodiment, the connector hole 208 may be formed on the third surface 200C of the electronic device 101 to accommodate a connector of an external device. A connection terminal (e.g., the connection terminal 178 of FIG. 1) electrically connected to a connector of an external device may be disposed in the connector hole 208. According to an embodiment, the electronic device 101 may include an interface module (e.g., the interface 177 of FIG. 1) for processing an electrical signal transmitted and received through the connection terminal.

According to an embodiment, the frame 218 may include a vent hole 206. For example, air outside the housing 210 may be introduced into the housing 210 through the vent hole 206. For example, the air inside the housing 210 may leak out to the outside of the housing 210 through the vent hole 206. A position of the vent hole 206 is not limited to a position illustrated in FIG. 2.

According to an embodiment, the electronic device 101 may include a light emitting element (not illustrated). For example, the light emitting element (not illustrated) may be disposed on the first surface 200A of the housing 210. The light emitting element (not illustrated) may provide state information of the electronic device 101 in an optical form. According to an embodiment, the light emitting element (not illustrated) may provide a light source linked with an operation of the first camera module 205. For example, the light emitting element (not illustrated) may include an LED, an IR LED, and/or a xenon lamp.

FIG. 3 is an exploded perspective view of an electronic device according to various embodiments.

Hereinafter, a redundant description of a configuration having an identical reference numeral as the above-described configuration may not be repeated.

Referring to FIG. 3, according to an embodiment, an electronic device 101 may include a frame 218, a bracket 243, a printed circuit board 250, a cover plate 260, and/or a battery 270. The printed circuit board 250 may include a first printed circuit board 251 as a main board and a second printed circuit board 252 as a sub-board.

According to an embodiment, the first printed circuit board 251 and the second printed circuit board 252 may be disposed on the bracket 243. For example, the first printed circuit board 251 and the second printed circuit board 252 may be disposed on a surface (e.g., a surface facing a-z direction) of the bracket 243. The first printed circuit board 251 may include a first surface 251a facing a rear side (e.g., the −z direction) of the electronic device 101 and a second surface 251b facing a front side (e.g., a +z direction) of the electronic device 101. The first printed circuit board 251 may be disposed on the bracket 243 such that the second surface 251b faces the surface of the bracket 243. The second printed circuit board 252 may include a third surface 252a facing a rear side of the electronic device 101 and a fourth surface 252b facing a front side of the electronic device 101. The second printed circuit board 252 may be disposed on the bracket 243 such that the fourth surface 252b faces the surface of the bracket 243. The second printed circuit board 252 may be spaced apart from the first printed circuit board 251.

According to an embodiment, the electronic device 101 may include the frame 218 forming an exterior (e.g., the third surface 200C of FIG. 2) of the electronic device 101 and the bracket 243 coupled to the inside of the frame 218. According to an embodiment, the frame 218 and the bracket 243 may be disposed between a display 201 and a cover plate 211. For example, the frame 218 may surround a space between the cover plate 211 and the display 201. A window 201b may be attached to the frame 218.

According to an embodiment, the bracket 243 may support or accommodate other components included in the electronic device 101. For example, the display 201 may be disposed on a surface of the bracket 243 facing a direction (e.g., the +z direction), and a portion of the display 201 may be supported by the bracket 243. For example, the first printed circuit board 251, the second printed circuit board 252, the battery 270, and a second camera module 212 may be disposed on another surface of the bracket 243, facing a direction (e.g., the-z direction) opposite to the direction. For example, the first printed circuit board 251, the second printed circuit board 252, the battery 270, and the second camera module 212 may each be seated in a recess defined by the frame 218 and/or the bracket 243.

According to an embodiment, the first printed circuit board 251, the second printed circuit board 252, and the battery 270 may be coupled to the bracket 243, respectively. For example, the first printed circuit board 251 and the second printed circuit board 252 may be fixedly disposed on the bracket 243 through a coupling member such as a screw. For example, the battery 270 may be fixedly disposed on the bracket 243 through an adhesive member (e.g., a double-sided tape). However, the disclosure is not limited by the above-described example.

According to an embodiment, the cover plate 260 may be disposed between the first printed circuit board 251 and the cover plate 211. According to an embodiment, the cover plate 260 may be disposed on the first printed circuit board 251. For example, the cover plate 260 may be disposed on a surface of the first printed circuit board 251 facing the-z direction.

According to an embodiment, the cover plate 260 may at least partially overlap the first printed circuit board 251 with respect to a z-axis. According to an embodiment, the cover plate 260 may cover at least a partial region of the first printed circuit board 251. Accordingly, the cover plate 260 may protect the first printed circuit board 251 from a physical impact or prevent (or reduce a likelihood of) a connector coupled to the first printed circuit board 251 from detaching.

According to an embodiment, the cover plate 260 may be fixedly disposed on the first printed circuit board 251 through a coupling member (e.g., a screw), or may be coupled to the bracket 243 together with the first printed circuit board 251 through the coupling member.

According to an embodiment, the display 201 may be disposed between the bracket 243 and the window 201b. For example, the window 201b may be disposed on a side (e.g., the +z direction) of a display panel 201a, and the bracket 243 may be disposed on another side (e.g., the −z direction).

According to an embodiment, the window 201b may be coupled to the display panel 201a. For example, the window 201b and the display panel 201a may be adhered to each other through an optical adhesive member (e.g., an optically clear adhesive (OCA) or an optically clear resin (OCR)) interposed therebetween.

According to an embodiment, the window 201b may be coupled to the frame 218. For example, when viewed in the z-axis direction, the window 201b may include an outer portion extending outside the display 201, and may be adhered to the frame 218 through an adhesive member (e.g., a waterproof tape) disposed between the frame 218 and the outer portion of the window 201b. However, the disclosure is not limited by the above-described example.

According to an embodiment, a processor (e.g., the processor 120 of FIG. 1), memory (e.g., the memory 130 of FIG. 1), and/or an interface (e.g., the interface 177 of FIG. 1) may be disposed on the first printed circuit board 251 and/or the second printed circuit board 252. The processor may include, for example, one or more of a central processing unit, an application processor, a graphic processing unit, an image signal processor, a sensor hub processor, or a communication processor. The memory may include, for example, volatile memory or non-volatile memory. The interface may include, for example, a high definition multimedia interface (HDMI), a universal serial bus (USB) interface, an SD card interface, and/or an audio interface. The interface may electrically or physically connect the electronic device 101 to an external electronic device, and may include a USB connector, an SD card/MMC connector, or an audio connector. According to an embodiment, the first printed circuit board 251 and the second printed circuit board 252 may be operatively or electrically connected to each other through a connection member (e.g., a flexible printed circuit board).

According to an embodiment, the battery 270 (e.g., the battery 189 of FIG. 1) may supply power to at least one component of the electronic device 101. For example, the battery 270 may include a rechargeable secondary battery or a fuel cell. At least a portion of the battery 270 may be disposed on substantially identical plane as the first printed circuit board 251 and/or the second printed circuit board 252.

According to an embodiment, the electronic device 101 may include an antenna module (not illustrated) (e.g., the antenna module 197 of FIG. 1). According to an embodiment, the antenna module may be disposed between the cover plate 211 and the battery 270. The antenna module may include, for example, a near field communication (NFC) antenna, a wireless charging antenna, and/or a magnetic secure transmission (MST) antenna. The antenna module may, for example, perform short-range communication with an external device or wirelessly transmit and receive power to and from the external device.

In an embodiment, a first camera module 205 (e.g., a front camera) may be disposed on at least a portion of the bracket 243 such that a lens may receive external light through a partial region (e.g., a camera region 237) of the window 201b (e.g., the front surface 200A of FIG. 2).

According to an embodiment, the second camera module 212 (e.g., a rear camera) may be disposed between the bracket 243 and the cover plate 211. According to an embodiment, the second camera module 212 may be electrically connected to the first printed circuit board 251 through a connection member (e.g., a connector). According to an embodiment, the second camera module 212 may be disposed so that a lens may receive external light through a camera region 284 of the cover plate 211 of the electronic device 101.

According to an embodiment, the camera region 284 may be formed on a surface (e.g., the rear surface 200B of FIG. 2) of the cover plate 211. According to an embodiment, the camera region 284 may be formed at least partially transparent so that external light may be incident on the lens of the second camera module 212. According to an embodiment, at least a portion of the camera region 284 may protrude from the surface of the cover plate 211 to a predetermined height. However, the disclosure is not limited thereto, and according to an embodiment, the camera region 284 may form substantially identical plane as the surface of the cover plate 211.

According to an embodiment, the housing 210 of the electronic device 101 may refer, for example, to a configuration or a structure forming at least a portion of the exterior of the electronic device 101. In this respect, at least a portion of the window 201b, the frame 218, the bracket 243, and/or the cover plate 211 forming the exterior of the electronic device 101 may be referred to as the housing 210 of the electronic device 101.

According to an embodiment, the electronic device 101 may include the cover plate 211. The cover plate 211 may define at least a portion of a rear surface (e.g., the second surface 200B of FIG. 2) of the electronic device 101. The cover plate 211 may be referred to as a rear cover or a back cover in terms of defining at least a portion of the rear surface of the electronic device 101. For example, the cover plate 211 may be opposite to the display (or the window 201b of the display) that forms at least a portion of the front surface (e.g., the first surface 200A of FIG. 2) of the electronic device 101. The window 201b of the display 201 may form at least a portion of the front surface of the electronic device 101, and the cover plate 211 may form at least a portion of the rear surface of the electronic device 101. The display may face substantially the +z direction, and the cover plate 211 may face substantially the −z direction.

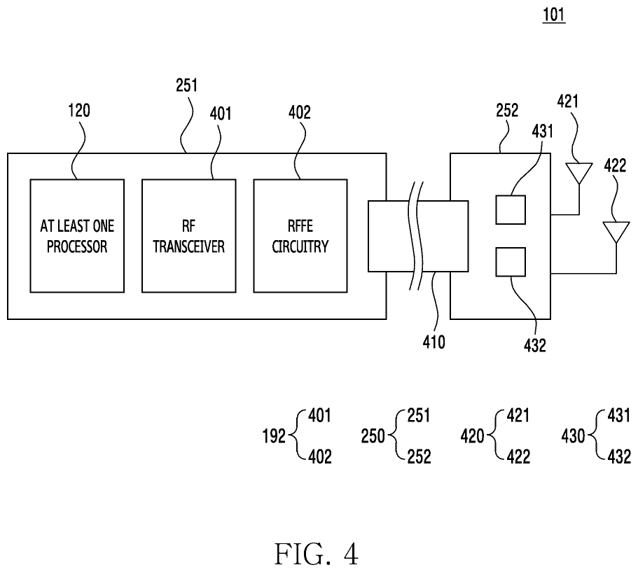

FIG. 4 is a block diagram illustrating an example configuration of an electronic device according to various embodiments.

Referring to FIG. 4, according to an embodiment, an electronic device 101 may include at least one processor (e.g., the processor 120 of FIG. 1). At least one processor 120 may include a processing circuit. At least one processor 120 may include an application processor (AP) (e.g., a central processing unit (CPU)) and/or a communication processor (CP) (e.g., a modem), but is not limited thereto. At least one processor 120 may include a graphic processing device (e.g., GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (DDI), an audio CODEC chip, a universal serial bus (USB) controller, a camera controller, an image processing IC, a microprocessor unit (MPU), a system on chip (SoC), an IC, or a circuit similar thereto.

According to an embodiment, the electronic device 101 may include wireless communication circuitry (e.g., the wireless communication module 192 of FIG. 1). The wireless communication circuitry 192 may include a radio frequency (RF) transceiver 401 and RF front end (RFFE) circuitry 402.

According to an embodiment, at least one processor 120 may generate a baseband signal. At least one processor 120 may control the RF transceiver 401 to process the generated baseband signal. At least one processor 120 may control the RF transceiver 401 to transmit a transmission signal through an antenna radiator 420. At least one processor 120 may control the RF transceiver 401 so that the transmission signal is transmitted in a frequency band capable of communicating with an external electronic device.

According to an embodiment, the RF transceiver 401 may be implemented as a single chip (e.g., an RFIC chip) or as a portion of a single package. The RF transceiver 401 may include a digital to analog converter (DAC) for converting a digital signal into an analog signal. The RF transceiver 401 may include a mixer and an oscillator (e.g., local oscillator (LO)) for an up-conversion. The RF transceiver 401 may convert the baseband signal generated by at least one processor 120 into an RF signal. The RF transceiver 401 may include an analog to digital converter (ADC) for converting the analog signal into the digital signal. The RF transceiver 401 may include a mixer and an oscillator for a down-conversion. The RF transceiver 401 may convert the RF signal received from the antenna radiator 420 into the baseband signal to be processed by at least one processor 120.

According to an embodiment, the RFFE circuitry 402 may include a plurality of components electrically connected between the RF transceiver 401 and the antenna radiator 420. For example, the RFFE circuitry 402 may include components such as a coupler, a power amplifier (PA), a low noise amplifier (LNA), switch circuitry, and/or a duplexer, but is not limited thereto.

According to an embodiment, the wireless communication circuitry 192 may be configured to communicate with an external electronic device using the antenna radiator 420. According to an embodiment, the antenna radiator 420 may include a feeding point where a feeding signal from the wireless communication circuitry 192 is provided, and a grounding point connected to a ground of the electronic device 101.

According to an embodiment, the electronic device 101 may include a first printed circuit board 251 and/or a second printed circuit board 252. The first printed circuit board 251 and the second printed circuit board 252 may include a plurality of conductive layers and a plurality of non-conductive layers stacked alternately with the plurality of conductive layers. The first printed circuit board 251 and the second printed circuit board 252 may provide an electrical connection between various electronic components using electrical wires and conductive vias formed in the plurality of conductive layers. The second printed circuit board 252 may be spaced apart from the first printed circuit board 251. For example, the first printed circuit board 251 may be referred to as a main printed circuit board, and the second printed circuit board 252 may be referred to as a sub-printed circuit board. For example, at least one processor 120 and the wireless communication circuitry 192 may be disposed on the first printed circuit board 251, which is the main printed circuit board. The second printed circuit board 252 may be electrically connected to the antenna radiator 420. In FIG. 4, the antenna radiator 420 is illustrated to be electrically connected to the second printed circuit board 252, but the electronic device 101 may further include other antenna radiators electrically connected to the first printed circuit board 251.

The antenna radiator 420, which is a physical component of the antenna, may be configured to radiate and/or receive an electromagnetic wave, by being fed from the wireless communication circuitry 192. The antenna radiator 420 may be configured to radiate the RF signals to the outside of the electronic device 101 based on feeding from the wireless communication circuitry 192. A type and performance of the antenna may be based on a physical structure of the antenna radiator 420. The antenna radiator 420 may include a first antenna radiator 421 and a second antenna radiator 422, but is not limited thereto.

According to an embodiment, since the wireless communication circuitry 192 is disposed on the first printed circuit board 251 and the antenna radiator 420 is electrically connected to the second printed circuit board 252, an electrical connection between the first printed circuit board 251 and the second printed circuit board 252 may be required to electrically connect the wireless communication circuitry 192 and the antenna radiator 420. According to an embodiment, the electronic device 101 may include a flexible printed circuit board 410 configured to electrically connect the first printed circuit board 251 and the second printed circuit board 252.

According to an embodiment, the electronic device 101 may include impedance circuitry 430. The impedance circuitry 430 may be configured to match the characteristic impedance of the transmission line with the impedance of the antenna and adjust a resonance frequency of the antenna, by being electrically connected to a transmission line electrically connected to the antenna radiator 420. For example, the impedance circuitry 430 may include one or more passive elements, such as a capacitor and/or an inductor, and switch circuitry. The impedance circuitry 430 may be configured to electrically connect the transmission line to one or more passive elements. For example, the impedance circuitry 430 may include first impedance circuitry 431 electrically connected to the first antenna radiator 421 and second impedance circuitry 432 electrically connected to the second antenna radiator 422.

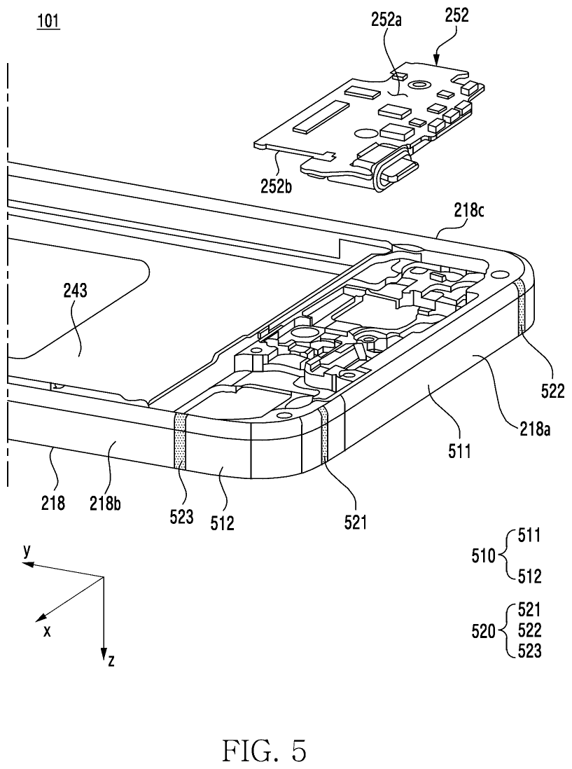

FIG. 5 is a partial exploded perspective view illustrating a portion of an electronic device according to various embodiments.

Referring to FIG. 5, a frame 218 may form at least a portion of a periphery of an electronic device 101. A bracket 243 may be surrounded by the frame 218.

According to an embodiment, the frame 218 may include a first periphery portion 218a, a second periphery portion 218b, and a third periphery portion 218c. For example, the first periphery portion 218a may be a lower periphery portion of the electronic device 101. The second periphery portion 218b may be connected to a side of the first periphery portion 218a and extend perpendicular to the first periphery portion 218a. The third periphery portion 218c may be opposite to the second periphery portion 218b. The third periphery portion 218c may be connected to another side of the first periphery portion 218a and extend perpendicular to the first periphery portion 218a. Although not illustrated in FIG. 5, the frame 218 may include a fourth periphery portion (not illustrated) opposite to the first periphery portion 218a. For example, the first periphery portion 218a may be parallel to an x-axis of FIG. 5, and the second periphery portion 218b and the third periphery portion 218c may be parallel to a y-axis of FIG. 5.

According to an embodiment, the frame 218 forming at least a portion of a periphery of the electronic device 101 may include one or more conductive portions 510 and one or more non-conductive portions 520. One or more conductive portions 510 may be formed of a conductive material (e.g., metal). One or more non-conductive portions 520 may be formed of a non-conductive material. One or more non-conductive portions 520 may physically separate one or more conductive portions 510 by being in contact with one or more conductive portions 510.

According to an embodiment, one or more conductive portions 510 may be configured to function as an antenna radiator (e.g., the antenna radiator 420 of FIG. 4). One or more conductive portions 510, as a physical component of an antenna, may be configured to radiate and/or receive an electromagnetic wave by being fed from wireless communication circuitry (e.g., the wireless communication module 192 of FIG. 1). One or more conductive portions 510 may include a feeding point that receives power through a transmission line. For example, the wireless communication circuitry may be configured to communicate with an external electronic device by feeding a feeding point of one or more conductive portions 510. When the feeding point of one or more conductive portions 510 is fed, a current (e.g., a radiation current) may flow along the one or more conductive portions 510. The current may form the electromagnetic wave around one or more conductive portions 510, and radio frequency (RF) signals may be radiated or received through the electromagnetic wave. Since an electrical length of the antenna affecting a radiation characteristic of the antenna is based on a structure of the antenna radiator 420, a type and a performance of the antenna including at least a portion of one or more conductive portions 510 configured to function as the antenna radiator 420 may be based on a physical structure of one or more conductive portions 510.

According to an embodiment, one or more conductive portions 510 may include a first conductive portion 511 and/or a second conductive portion 512. The first conductive portion 511 may extend between a first non-conductive portion 521 and a second non-conductive portion 522 disposed in the first periphery portion 218a. The second conductive portion 512 may extend between the first non-conductive portion 521 and a third non-conductive portion 523 disposed in the second periphery portion 218b. A structure of one or more conductive portions 510 and one or more non-conductive portions 520 described above are merely examples for convenience of explanation, and embodiments of the present disclosure are not limited thereto. The frame 218 may further include other conductive portions in addition to the first conductive portion 511 and the second conductive portion 512.

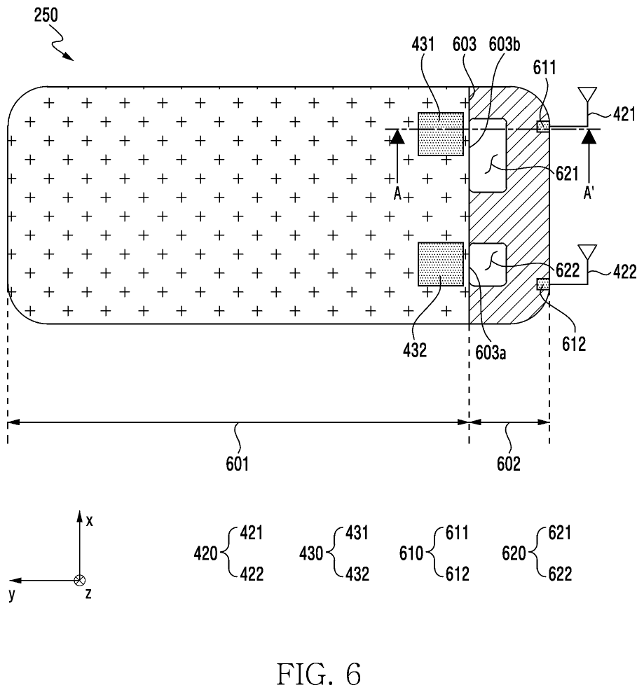

According to an embodiment, the first conductive portion 511 and/or the second conductive portion 512 may be configured to function as the antenna radiator 420 by being fed from the wireless communication circuitry. For example, the first conductive portion 511 may correspond to a first antenna radiator (e.g., the first antenna radiator 421 of FIG. 4), and the second conductive portion 512 may correspond to a second antenna radiator (e.g., the second antenna radiator 422 of FIG. 4). In case that the first periphery portion 218a is a lower periphery portion of the electronic device 101, the first conductive portion 511 and/or the second conductive portion 512 may be adjacent to a second printed circuit board 252. The first conductive portion 511 and/or the second conductive portion 512 may be electrically connected to the second printed circuit board 252 through an antenna contact (e.g., an antenna contact 610 of FIG. 6). In the present disclosure, the first conductive portion 511 and/or the second conductive portion 512 of the frame 218 forming at least a portion of a periphery of the electronic device are described as examples of the antenna radiator, but embodiments of the present disclosure are not limited thereto. For example, an antenna that includes an antenna radiator (e.g., the antenna radiator 420 of FIG. 4) may include a laser direct structuring (LDS) antenna or an FPCB antenna, and may include an antenna (e.g., mmWave module) provided in a form of a module.

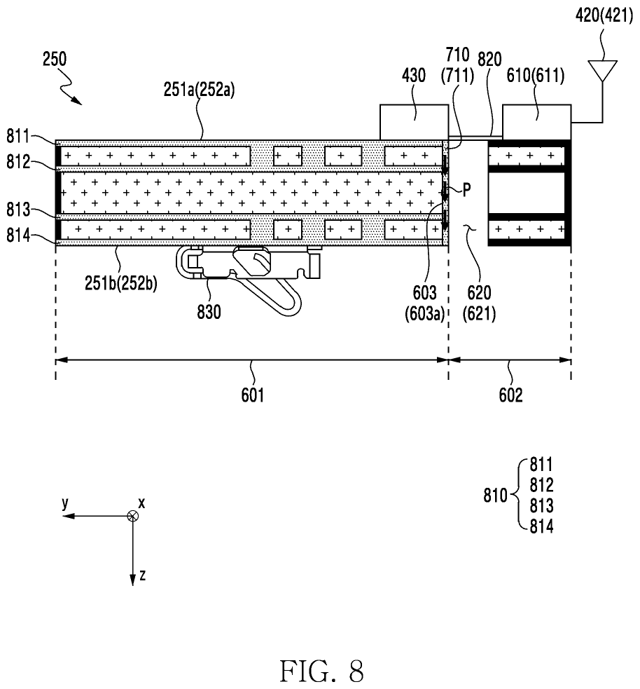

According to an embodiment, the bracket 243 may be configured to function as a ground of the electronic device 101. The printed circuit board 250 may be electrically connected to the bracket 243 configured to function as a ground. For example, the printed circuit board 250 may include at least one ground layer (e.g., a fourth conductive layer 814 of FIG. 8) electrically connected to the bracket 243. Electronic components electrically connected to the printed circuit board 250 may be electrically connected to the bracket 243 through at least one ground layer. For example, since the printed circuit board 250 is disposed on a surface of the bracket 243, at least one ground layer may be a layer adjacent to another surface (e.g., the second surface 251b or the fourth surface 252b of FIG. 3) of the printed circuit board 250 facing the bracket 243.

A current flow of a closed circuit forms a closed circuit that flows from a positive terminal of a battery to a load and then back to a negative terminal of the battery. The ground of the electronic device 101 is electrically connected to the negative terminal of the battery, and a current from a load (e.g., an electronic component) flows to the ground. A path of the current flowing through the electronic component to the ground may be referred to as a ground path or a return path. For example, a current from impedance circuitry (e.g., the impedance circuitry 430 of FIG. 4) disposed on the second printed circuit board 252 may flow to a ground layer of the second printed circuit board 252 and to the bracket 243 configured to function as a ground through the ground layer. The printed circuit board 250 may include a conductive via for a return path. The conductive via may be configured to electrically connect the ground layer to conductive layers of the printed circuit board 250.

Flow of a current flowing along the return path may cause a parasitic effect. A virtual parasitic impedance such as parasitic inductance may be caused around the return path by the flow of the current flowing along the return path. The parasitic impedance may cause radiated spurious emissions (RSE) in which an unintentional electromagnetic wave is radiated by causing harmonic noise when one or more conductive portions 510 are fed. The electromagnetic wave may cause noise, signal distortion, or a communication failure by electromagnetically interfering with RF signals transmitted and/or received through one or more conductive portions 510. To decrease the above problems, a conductive via connected to the ground layer may be formed as a through-via formed by penetrating entire layers of the printed circuit board 250. Since a length of the return path may be decreased by the through-via, the parasitic inductance may be decreased.

The printed circuit board 250 may include a fill-cut region (e.g., a second PCB portion 602 of FIG. 6). The fill-cut region is a region where at least a portion of a copper foil of the printed circuit board 250 is cut, and is distinguished from a fill region (e.g., a first PCB portion 601 of FIG. 6) where the copper foil is not cut. At least a portion of the copper foil cut in the fill-cut region may be a ground layer. For example, the fill-cut region may be formed in a region of the printed circuit board 250 electrically connected to the antenna radiator 420. In case that the antenna radiator 420 is electrically connected to the fill region, since the copper foil in the fill region includes a conductive material (e.g., copper), the copper foil in the fill region may affect a radiation characteristic of the antenna radiator 420. In order to decrease the length of the return path, the through-via may be disposed adjacent to the boundary of the fill region in contact with the fill-cut region.

For example, since the through-via is formed by penetrating the entire layers of the printed circuit board 250, an area in which electronic components may be disposed may be decreased by an area in which the through-via is formed. In order to implement various functions of the electronic device 101, as various electronic components are disposed in a housing, complexity of an electrical wire of the printed circuit board 250 may increase. In order to decrease the parasitic inductance, in case that the printed circuit board 250 includes the through-via, an area for electrically connecting electronic components to the printed circuit board 250 may be insufficient. In order to dispose the electronic components on the printed circuit board 250, in case that the through-via moves away from a boundary of the fill region, the length of the return path increases, which may cause the parasitic inductance.

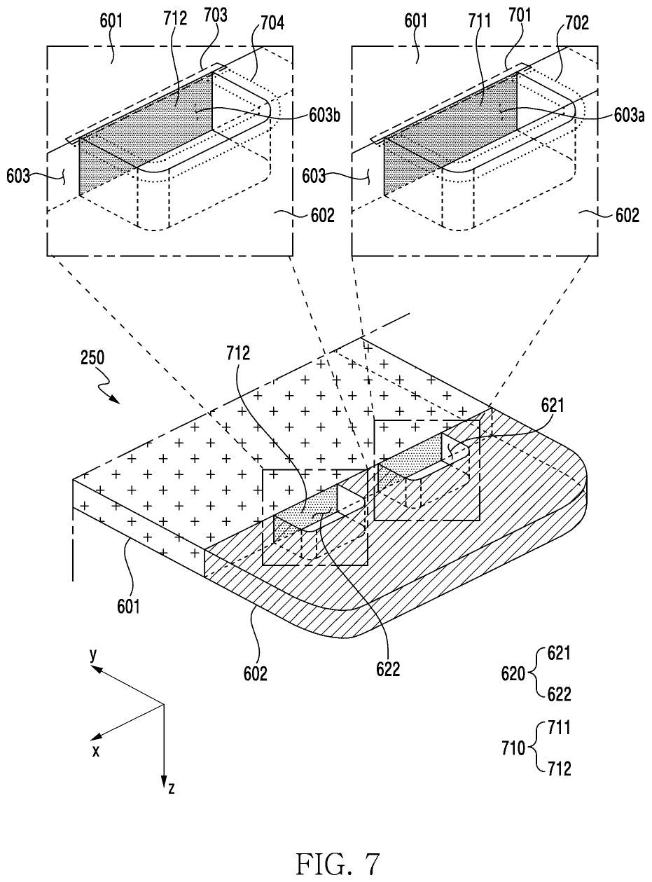

According to an embodiment, the printed circuit board 250 may include a conductive material (e.g., a conductive material 710 of FIG. 7) for providing the return path flowing to the ground layer in place of the through-via. The conductive material 710 may be referred to as a conductive trace. The fill-cut region may include an opening (e.g., an opening 620 of FIG. 6) partially exposing a lateral side (e.g., the lateral side 603 of FIG. 6) of the fill region in contact with the fill-cut region, and the conductive material 710 may be formed by plating a lateral side of the fill region exposed through the opening 620.

Below, a structure of the printed circuit board 250 including the conductive material 710 plated on the lateral side of the fill region will be described. The structure of the printed circuit board 250 described below may be applied to both a first printed circuit board 251 and a second printed circuit board 252. For convenience of explanation, it is explained that the electronic device 101 includes the first antenna radiator (e.g., the first antenna radiator 421 of FIG. 4) and the second antenna radiator (e.g., the second antenna radiator 422 of FIG. 4) but, as described above, embodiments of the present disclosure are not limited thereto.

FIG. 6 is a diagram illustrating a plan view of a printed circuit board according to various embodiments. FIG. 7 is a partial perspective view of a printed circuit board according to various embodiments. FIG. 8 is a cross-sectional view of a printed circuit board of FIG. 6 taken along line A-A′ according to various embodiments.

A structure of a printed circuit board 250 described below may be referred to as a structure of the first printed circuit board 251 and/or the second printed circuit board 252 of FIG. 3.

Referring to FIG. 6, the printed circuit board 250 may include a first PCB portion 601 and a second PCB portion 602. The second PCB portion 602 may be disposed alongside the first PCB portion 601. The first PCB portion 601 is the above-described fill region and may be referred to as a region of the printed circuit board 250 including at least one ground layer (e.g., a fourth conductive layer 814 of FIG. 8). For example, the first PCB portion 601 may include at least one ground layer electrically connected to the ground of the electronic device 101. The second PCB portion 602 is a fill-cut region where a ground layer is cut, and may be referred to as a region of the printed circuit board 250 that does not include the ground layer. The ground layer may be included in the first PCB portion 601, or may not be included in the second PCB portion 602. For example, the second PCB portion 602 may be insulated from at least one ground layer of the first PCB portion 601. The second PCB portion 602 being insulated from at least one ground layer of the first PCB portion 601, may be referred to as the second PCB portion 602 not including a ground layer that is electrically connected to the ground of the electronic device 101.

According to an embodiment, an antenna radiator 420 may be electrically connected to the second PCB portion 602 of the printed circuit board 250. For example, an antenna contact 610 for electrically connecting the printed circuit board 250 and the antenna radiator 420 may be disposed (or mounted) on the second PCB 602. A feeding signal provided from wireless communication circuitry (e.g., the wireless communication module 192 of FIG. 1) may be provided to the antenna radiator 420 through the printed circuit board 250 and the antenna contact 610. Since the antenna radiator 420 is electrically connected to the second PCB portion 602, the antenna radiator 420 and the ground layer may be spaced apart from each other. As the ground layer and the antenna radiator 420 are spaced apart by the second PCB portion 602, electromagnetic interaction between the ground layer and the antenna radiator 420 may decrease. As described above, the antenna radiator 420 may include one or more conductive portions (e.g., one or more conductive portions 510 of FIG. 5) included in a frame (e.g., frame 218 of FIG. 5). However, the antenna radiator 420 of the present disclosure is not limited to the one or more conductive portions. For example, the antenna radiator 420 may include a radiator of a laser direct structuring (LDS) antenna, a radiator of an FPCB antenna, or a radiator of an antenna module (e.g., a mmWave module). In addition to this, various embodiments may be possible.

According to an embodiment, the printed circuit board 250 may include an opening 620. The opening 620 may be formed by penetrating from a surface (e.g., the first surface 251a and the third surface 252a of FIG. 3) of the printed circuit board 250 to another surface (e.g., the second surface 251b and the fourth surface 252b of FIG. 3). The opening 620 may be positioned in the second PCB portion 602 to be in contact with a portion (e.g., a first portion 603a or a second portion 603b) of a lateral side 603 of the first PCB portion 601. Before a conductive material (e.g., a conductive material 710 of FIG. 7) to be described later is plated, the opening 620 may expose the portion of the lateral side 603 of the first PCB portion 601. The lateral side 603 of the first PCB portion 601 partially exposed through the opening 620 may be in contact with the second PCB portion 602. For example, the lateral side 603 of the first PCB portion 601 exposed through the opening 620 may be referred to as a boundary or a periphery of the first PCB portion 601. Since the first PCB portion 601 is a region of the printed circuit board 250 including the ground layer, the ground layer may be included in the lateral side 603 exposed through the opening 620. According to an embodiment, the opening 620 may be provided in plural. For example, the opening 620 may include a first opening 621 and/or a second opening 622. For example, the first opening 621 may expose the first portion 603a of the lateral side 603 of the first PCB portion 601. The second opening 622 may expose the second portion 603b of the lateral side 603 of the first PCB portion 601.

As described above, the antenna radiator 420 may be electrically connected to the second PCB portion 602 of the printed circuit board 250. As the second PCB portion 602 to which the ground layer is cut is electrically connected to the antenna radiator 420, the influence of the ground layer on the antenna radiator 420 may be decreased.

According to an embodiment, impedance circuitry 430 may be disposed on the first PCB portion 601 of the printed circuit board 250. The impedance circuitry 430 may be configured to match characteristic impedance of a transmission line with the impedance of an antenna and adjust a resonant frequency of the antenna, by being electrically connected to the transmission line that is electrically connected to the antenna radiator 420. Since the antenna radiator 420 is electrically connected to the second PCB portion 602 of the printed circuit board 250, the impedance circuitry 430 may be disposed on the first PCB portion 601 to be adjacent to the second PCB portion 602 to decrease signal loss. For example, the impedance circuitry 430 may be disposed adjacent to the opening 620. For example, the impedance circuitry 430 may include first impedance circuitry 431 for a first antenna radiator 421 and/or second impedance circuitry 432 for a second antenna radiator 422. For example, a second antenna contact 612 is electrically connected to the second antenna radiator 422. The second antenna radiator 422 is electrically connected to the printed circuit board 250, via the second antenna contact 612.

Referring to FIG. 7, a first opening 621 may be defined by a lateral side 603a of an edge portion 701 of a first PCB portion 601 and a lateral side of an edge portion 702 of a second PCB portion 602. A second opening 622 may be defined by a lateral side 603b of another edge portion 703 of the first PCB portion 601 and a lateral side of another edge portion 704 of the second PCB portion 602. The second opening 622 may be spaced apart from the first opening 621. The second opening 622 may be formed in the second PCB portion 602.

According to an embodiment, a conductive material 710 may be plated on a lateral side 603 of the first PCB portion 601 exposed through the opening 620 formed in the second PCB portion 602. The conductive material 710 may be plated on the lateral side (e.g., the lateral side 603a or the lateral side 603b) of the first PCB portion 601 exposed through the opening 620. As the conductive material 710 is plated on the lateral side 603a and 603b, the lateral side 603a and 603b may not be visually recognized from the outside. For example, the conductive material 710 may be plated on the lateral side 603a of the edge portion 701 of the first PCB portion 601 of the lateral side 603a of the edge portion 701 of the first PCB portion 601, and the lateral side of the edge portion 702 of the second PCB portion 602, which defines the first opening 621.

According to an embodiment, the conductive material 710 disposed on the lateral side 603a and 603b of the first PCB portion 601 exposed through the opening 620 may be physically and electrically connected to at least one ground layer of the first PCB portion 601. At least one ground layer included in the first PCB portion 601 may be exposed through the lateral side 603a and 603b of the first PCB portion 601 exposed through the opening 620. Since the conductive material 710 is plated on the lateral side 603a and 603b of the first PCB portion 601, the conductive material 710 may be connected to at least one ground layer. The conductive material 710 being connected to at least one ground layer may be referred to as the conductive material 710 being in contact with at least one ground layer.

According to an embodiment, the conductive material 710 may be configured to provide a substantially identical function as a through-via. Since the opening 620 is formed by penetrating the printed circuit board 250, the lateral side 603a and 603b of the first PCB portion 601 exposed through the opening 620 may expose all the layers included in the first PCB portion 601. When the conductive material 710 is plated on the lateral side 603a and 603b of the first PCB portion 601, the conductive material 710 is electrically connected to substantially all of the layers included in the first PCB portion 601, and electrically connected to at least one ground layer, so the conductive material 710 may be configured to provide a substantially identical function as a through-via.

Referring to FIG. 8, a printed circuit board 250 may include a plurality of conductive layers 810. For example, the printed circuit board 250 may include four conductive layers, but is not limited thereto. The plurality of conductive layers 810 may be electrically connected through a conductive via. A non-conductive layer may be interposed between the plurality of conductive layers 810. For example, the plurality of conductive layers 810 may include a first conductive layer 811 (e.g., electrical wire), a second conductive layer 812, a third conductive layer 813, and a fourth conductive layer 814. The first conductive layer 811, the second conductive layer 812, the third conductive layer 813, and the fourth conductive layer 814 may be sequentially stacked with the non-conductive layers interposed therebetween. For example, the first conductive layer 811 may be disposed on a surface (e.g., the first surface 251a or the third surface 252a) of the printed circuit board 250 facing (e.g., facing the −z direction) a rear side of an electronic device 101. The fourth conductive layer 814 may be disposed on another surface (e.g., a second surface 251b or a fourth surface 252b) of the printed circuit board 250 facing (e.g., facing a +z direction) a front side of the electronic device 101. The second conductive layer 812 and the third conductive layer 813 may be disposed between the first conductive layer 811 and the fourth conductive layer 814.

According to an embodiment, the other surface of the printed circuit board 250 may be electrically connected to a ground of the electronic device 101. For example, a ground layer may be electrically connected to a bracket (e.g., the bracket 243 of FIG. 5) configured to function as the ground of the electronic device 101 through a conductive connecting part 830. The conductive connecting part 830 may electrically connect the ground layer to the bracket 243 by contacting the ground layer and the bracket 243. The conductive connecting part 830 may be referred to as a conductive clip, a conductive pin, or a conductive contact. The other surface 251b or 252b of the printed circuit board 250 on which the fourth conductive layer 814 is disposed may face the bracket 243 so that the ground layer may be connected to the bracket 243 through the conductive connecting part 830. The fourth conductive layer 814 may be referred to as the ground layer.

According to an embodiment, since a conductive material 710 is physically and electrically connected to at least one ground layer included in the first PCB portion 601, the conductive material 710 may be configured to provide a portion P of a return path flowing to the ground. For example, the return path may be formed from impedance circuitry 430 along the conductive material 710, the ground layer, the conductive connecting part 830, and the bracket 243. For example, a first antenna contact 611 may be electrically connected to a first antenna radiator (e.g., the first antenna radiator 421 of FIG. 4). First impedance circuitry 431 may be electrically connected to a transmission line 820 connected to the first antenna contact 611. A portion of the return path flowing from the first impedance circuitry 431 to the ground may be formed as the fourth conductive layer 814 from the first impedance circuitry 431 along a first conductive material 711 disposed on a first portion 603a of the lateral side 603. The portion P of the return path provided by the conductive material 710 may be referred to as a portion formed from the first conductive layer 811 to the fourth conductive layer 814 corresponding to the ground layer along the conductive material 710 in an entire return path formed from the impedance circuitry 430 to the bracket 243.

As described above, since the opening 620 is formed by penetrating a surface of the printed circuit board 250 to another surface of the printed circuit board 250, a thickness of the lateral side 603 of the first PCB portion 601 exposed through the opening 620 may correspond to a minimum distance between the first conductive layer 811 and the fourth conductive layer 814. Since the conductive material 710 is disposed on the lateral side, a thickness of the conductive material 710 may substantially correspond to a thickness of the first PCB portion 601 of the printed circuit board 250. The portion P of the return path formed along the conductive material 710 may be configured to function substantially identically to a conductive via. Since the portion P of the return path formed along the conductive material 710 may be formed at a minimum distance from the first conductive layer 811 to the fourth conductive layer 814, a total length of the return path may be decreased. Since the total length of the return path including the portion of the return path formed through the conductive material 710 may be decreased, the conductive material 710 may decrease parasitic impedance. Due to the decrease in the parasitic impedance, harmonic noise may be decreased, and communication quality of the electronic device 101 may be improved.

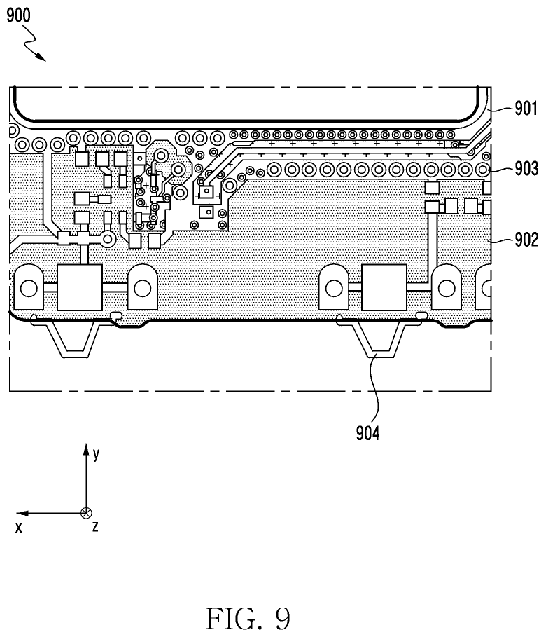

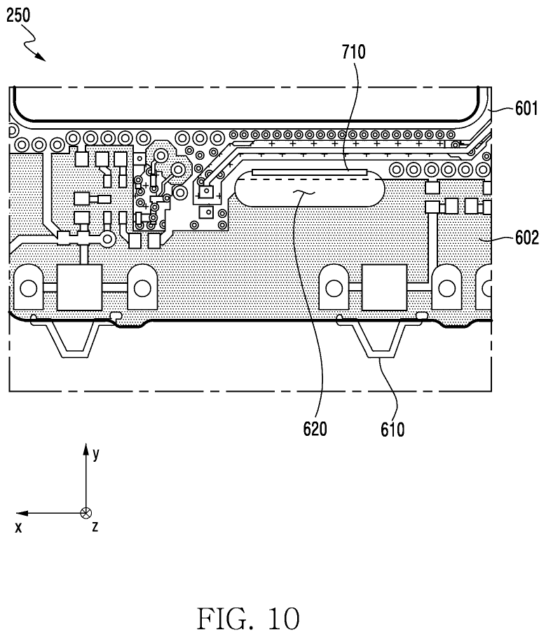

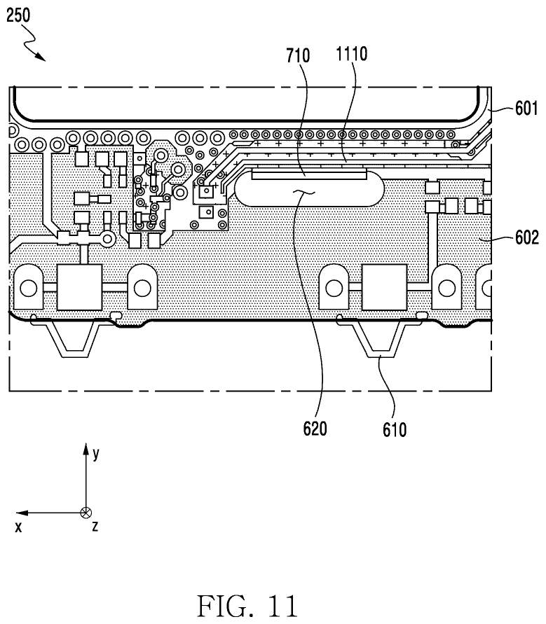

FIG. 9 is a diagram illustrating a portion of a printed circuit board according to a comparative example. FIGS. 10 and 11 are diagrams illustrating a portion of a printed circuit board including an opening according to various embodiments.

FIG. 9 illustrates a printed circuit board 900 according to a comparative example that does not include an opening 620. The printed circuit board 900 according to the comparative example may include a fill region 901 including a ground layer and a fill-cut region 902 not including the ground layer. Through-vias 903 adjacent to a boundary between the fill region 901 and the fill-cut region 902 may be disposed in the fill region 901. The through-vias 903 may be formed by penetrating the printed circuit board 900 according to the comparative example.

As the printed circuit board 900 according to the comparative example includes the through-vias 903, an area in which electronic components and electrical wires electrically connected to the electronic components may be disposed may be decreased. Since the through-vias 903 are formed by penetrating the printed circuit board 900 according to the comparative example, electronic components and electrical wires for the electronic components may not be disposed in the area in which the through-vias 903 are disposed. In a case of the printed circuit board 900 according to the comparative example, since a distance between an antenna contact 904 and the fill area 901 including the ground layer is relatively close, electromagnetic interaction between the antenna and the ground layer may occur relatively easily.

Referring to FIG. 10, according to an embodiment, a printed circuit board 250 may include an opening 620. A conductive material 710 may be disposed on a lateral side 603 of a first PCB portion 601 exposed through the opening 620. Since the conductive material 710 may replace a through-via, in a case of the printed circuit board 250, an area in which electronic components may be disposed may be relatively large. In order to provide various functions through an electronic device (e.g., the electronic device 101 of FIG. 5), the number of electronic components included in the electronic device 101 may be increased. In a case of the printed circuit board 250 including the opening 620, since it does not include a through-via, a relatively large number of electronic components may be disposed.

According to an embodiment, in case that an area of the opening 620 is increased, a distance between the first PCB portion 601 including a ground layer and an antenna contact 610 may be relatively increased. In case of removing the through-vias and expanding the opening 620 by a region where the removed through-vias were disposed, a distance between the antenna contact 610 and the first PCB portion 601 may be increased. As the distance between the antenna contact 610 and the first PCB portion 601 is relatively increased, the distance between the antenna and the ground layer may be relatively increased. According to an embodiment, since electromagnetic interaction between the antenna and the ground layer may decrease, performance of the antenna may be improved.

Referring to FIG. 11, a printed circuit board 250 may secure an area capable of including at least one electrical wire 1110 for electronic components by removing through-vias disposed in a first PCB portion 601. For example, in case that the through-vias are replaced with the conductive material 710, at least a portion of an area occupied by the through-vias may be additionally secured. At least one electrical wire 1110 for an electrical connection with an electronic component may be added in a portion secured by removing the through-vias. As the at least one electrical wire 1110 is added, the printed circuit board 250 may be electrically connected to a relatively large number of electronic components.

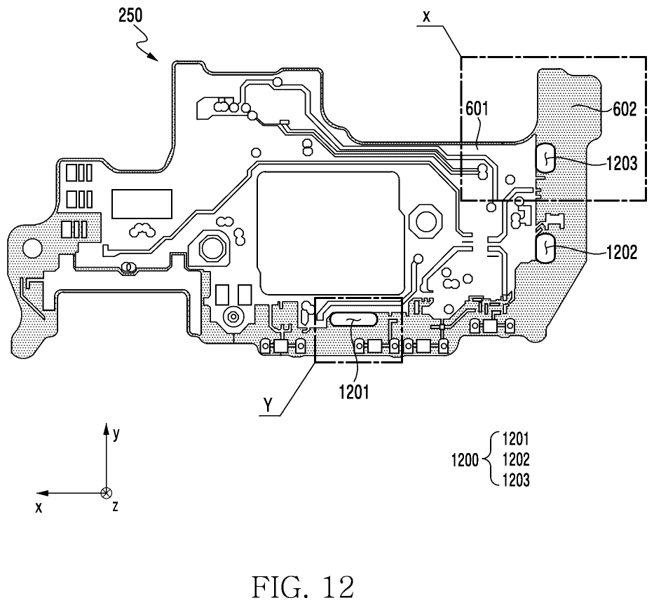

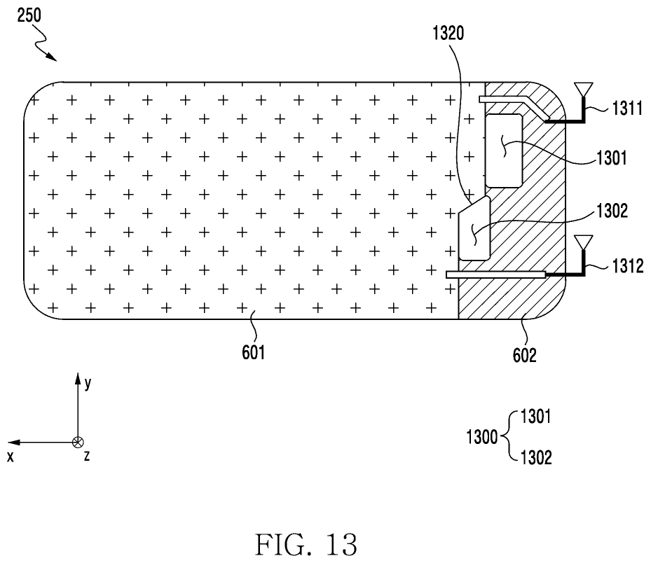

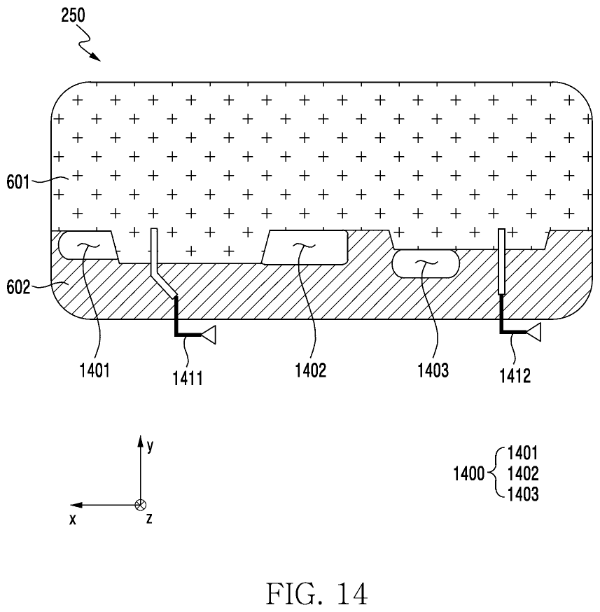

FIG. 12 is a diagram illustrating a plan view of a printed circuit board according to various embodiments. FIG. 13 is a diagram illustrating an example of an X region of FIG. 12 in a printed circuit board according to various embodiments. FIG. 14 illustrates an example of a Y region of FIG. 12 in a printed circuit board according to various embodiments.

Referring to FIG. 12, a printed circuit board 250 may include a plurality of openings 1200 (e.g., the opening 620 of FIG. 6). For example, the plurality of openings 1200 may include a first opening 1201, a second opening 1202, and a third opening 1203 disposed at different positions in a second PCB portion 602 of the printed circuit board 250. At the positions where the first opening 1201, the second opening 1202, and the third opening 1203 are formed, portions of a lateral side 603 of a first PCB portion 601 may be exposed. Conductive materials (e.g., the first conductive material 711 and the second conductive material 712 of FIG. 7) may be plated on portions of the lateral side (e.g., the lateral side 603 of FIG. 6) of the first PCB portion 601 exposed through the first opening 1201, the second opening 1202, and the third opening 1203, respectively. Each of the conductive materials may be configured to function substantially identically to the through-via. According to an embodiment, the printed circuit board 250 may remove the through-vias and provide a portion of a ground path through conductive materials 710 plated in the corresponding region. The first opening 1201, the second opening 1202, and the third opening 1203 are only examples for explaining the plurality of openings 1200 disposed at different positions of the printed circuit board 250, and embodiments of the present disclosure are not limited to a structure illustrated in FIG. 12.

Referring to FIG. 13, antenna radiators 1311 and 1312 (e.g., the antenna radiator 430 of FIG. 4) may be electrically connected to a side of a second PCB portion 602. For example, the side of the second PCB portion 602 to which the antenna radiators 1311 and 1312 are electrically connected may face a-x direction of FIG. 13. As the antenna radiators 1311 and 1312 are electrically connected to the side of the second PCB portion 602, openings 1300 (e.g., the opening 620 of FIG. 6) may be formed on another side of the second PCB portion 602 opposite to the side of the second PCB portion 602. For example, the antenna radiators 1311 and 1312 may include a first antenna radiator 1311 and a second antenna radiator 1312, and the opening 1300 may include a first opening 1301 adjacent to the first antenna radiator 1311 and a second opening 1302 adjacent to the second antenna radiator 1312. The first opening 1301 and the second opening 1302 may be formed along a portion of a periphery of the second PCB portion 602 facing the x direction.

According to an embodiment, according to a shape or a structure of a boundary between a first PCB portion 601 and the second PCB portion 602, a shape of the opening 1300 may vary. For example, the opening 1300 may include an inclined surface that is at least partially inclined. In case that the opening 1300 includes the inclined surface, a lateral side (e.g., the lateral side 603 of FIG. 6) of the first PCB portion 601 exposed through the opening 1300 may include an inclined portion 1320 by being exposed through the inclined surface. The inclined portion 1320 may be referred to as a portion having an inclination with respect to the x-axis or y-axis of FIG. 13. The boundary between the first PCB portion 601 and the second PCB portion 602 may be formed in various shapes according to a size and a structure of a printed circuit board 250, the number, a shape, and a size of electronic components electrically connected to the printed circuit board 250, or a position of the printed circuit board 250 in the electronic device 101. According to the shape between the first PCB portion 601 and the second PCB portion 602, the opening 1300 may be formed in various shapes, so the lateral side 603 of the first PCB portion 601 exposed through the opening 1300 may have various shapes in addition to a linearly extending portion or the inclined portion 1320.

Referring to FIG. 14, antenna radiators 1411 and 1412 (e.g., the antenna radiator 420 of FIG. 4) may be electrically connected to a lower portion of a second PCB portion 602. For example, the lower portion of the second PCB portion 602 to which the antenna radiators 1411 and 1412 are electrically connected may face a −y direction of FIG. 14. For example, as the antenna radiators 1411 and 1412 are electrically connected to the lower portion of the second PCB portion 602, an opening 1400 may be formed on an upper portion (e.g., a +y direction) of the second PCB portion 602 opposite to the lower portion (e.g., a −y direction) of the second PCB portion 602. For example, the upper portion of the second PCB portion 602 may face the +y direction. For example, the opening 1400 may include a first opening 1401, a second opening 1402, and a third opening 1403, and the antenna radiators 1411 and 1412 may include a first antenna radiator 1411 disposed between the first opening 1401 and the second opening 1402 and a second antenna radiator 1412 disposed between the second opening 1402 and the third opening 1403. The first opening 1401, the second opening 1402, and the third opening 1403 may be formed along a portion of a periphery of the second PCB portion 602 facing the +y direction. For example, the opening 1400 may be variously formed according to a shape of a boundary surface between the first PCB portion 601 and the second PCB portion 602. Conductive materials (e.g., the first conductive material 711 and the second conductive material 712 of FIG. 7) may be formed according to a shape of a lateral side 603 of the first PCB portion 601.

FIGS. 13 and 14 may illustrate an example of a printed circuit board 250 in order to explain that an opening 620 may be formed at various positions of the printed circuit board 250. Embodiments of the present disclosure are not limited to a structure of the printed circuit board 250 illustrated in FIG. 13 or 14.

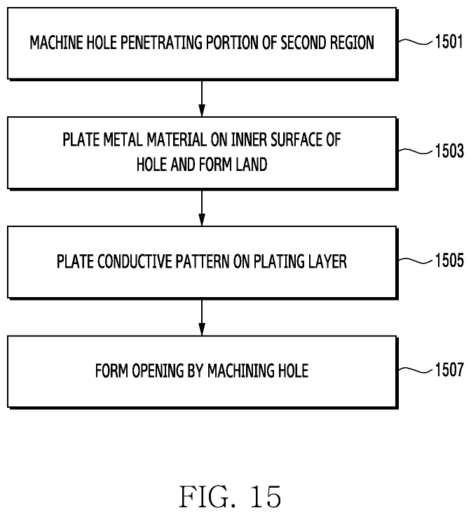

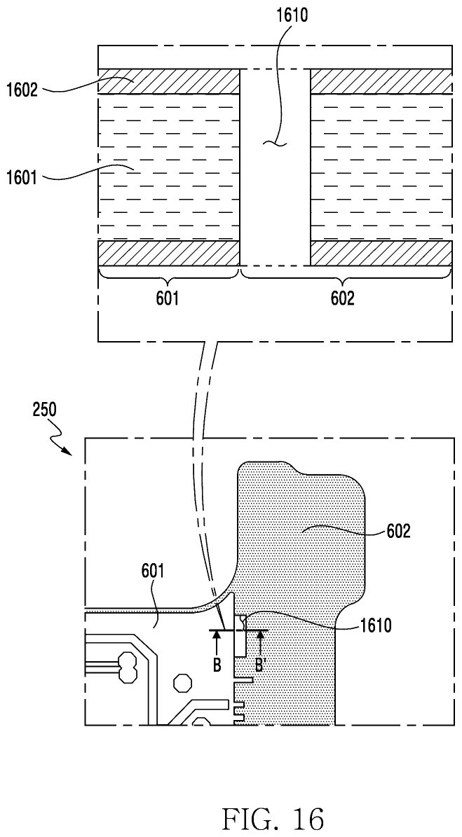

FIG. 15 is a flowchart illustrating an example process of forming a conductive material of a printed circuit board according to various embodiments. FIGS. 16, 17, 18, 19, and 20 are diagrams illustrating various example processes of forming an opening according to various embodiments.

According to an embodiment, a conductive material 710 may be formed by forming an opening 620 in a printed circuit board 250 and then plating a portion of a lateral side 603 of a first PCB portion 601 exposed through the opening 620 with a conductive material. An example process forming the conductive material 710 will be described below.

Referring to FIG. 15, in a process 1501, a hole penetrating a portion of a second PCB portion 602 of a printed circuit board 250 may be machined.

FIG. 16 illustrates a portion of the printed circuit board 250 on which a hole 1610 is machined. Referring to FIG. 16, the hole 1610 may be machined in the second PCB portion 602. The hole 1610 may expose a lateral side 603 of a first PCB portion 601 by being positioned in the second PCB portion 602 in contact with the first PCB portion 601. For example, the hole 1610 may be formed through a computerized numerical control (CNC) processing. Referring to a cross-sectional view of the printed circuit board 250 of FIG. 16 cut along line B-B′, the hole 1610 may be formed by penetrating a non-conductive layer 1601 and a conductive layer 1602 of the printed circuit board 250.

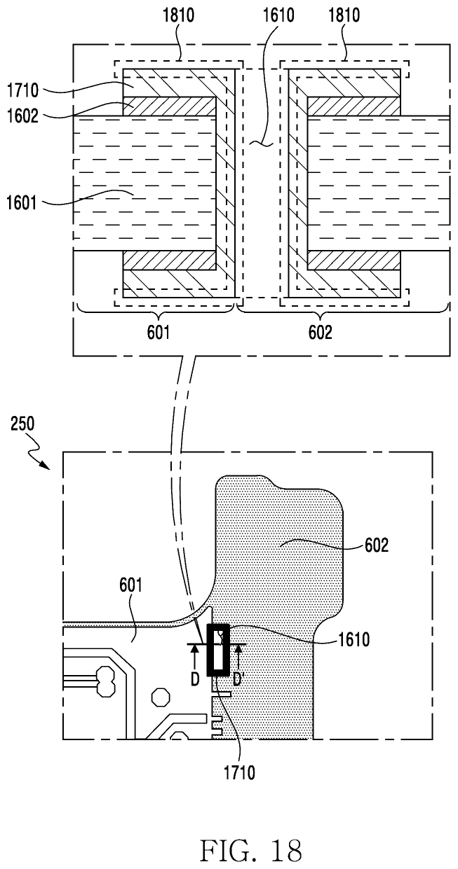

Referring again to FIG. 15, in a process 1503, a metal material is plated on an inner surface of the hole 1610 to form a plating layer, and a land (e.g., a land 1810 of FIG. 18) may be formed.

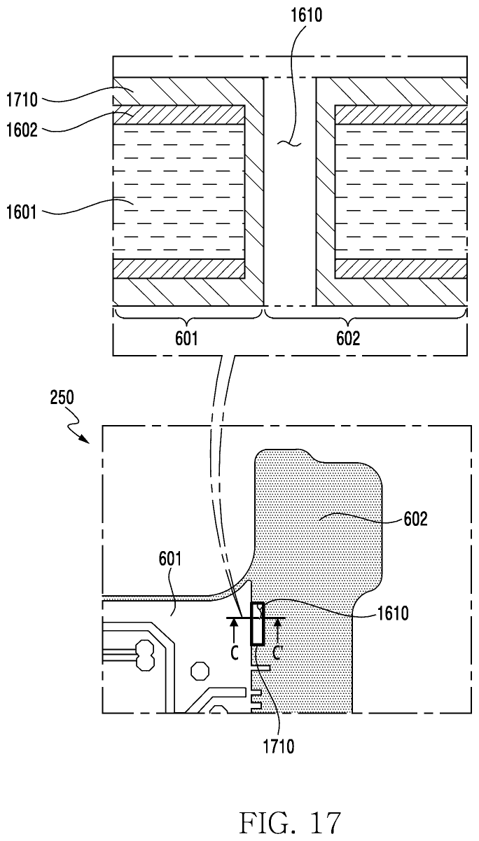

Referring to FIG. 17, a metal material (e.g., copper) may be plated on an inner surface of the hole 1610 to form a plating layer 1710. Referring to a cross-sectional view of the printed circuit board 250 of FIG. 17 cut along line C-C′, the plating layer 1710 may be formed on an inner surface of the hole 1610 and the conductive layer 1602.

Referring to FIG. 18, a land including a plating layer 1710 formed on an inner surface of the hole 1610 may be formed. The land 1810 may be referred to as a pad, which is a portion where an electronic component may be coupled. Referring to a cross-sectional view of the printed circuit board 250 of FIG. 18 cut along line D-D′, the land 1810 may be formed by machining the conductive layer 1602 and the plating layer 1710.

Referring again to FIG. 15, in a process 1505, a conductive material 710 may be plated on the plating layer.

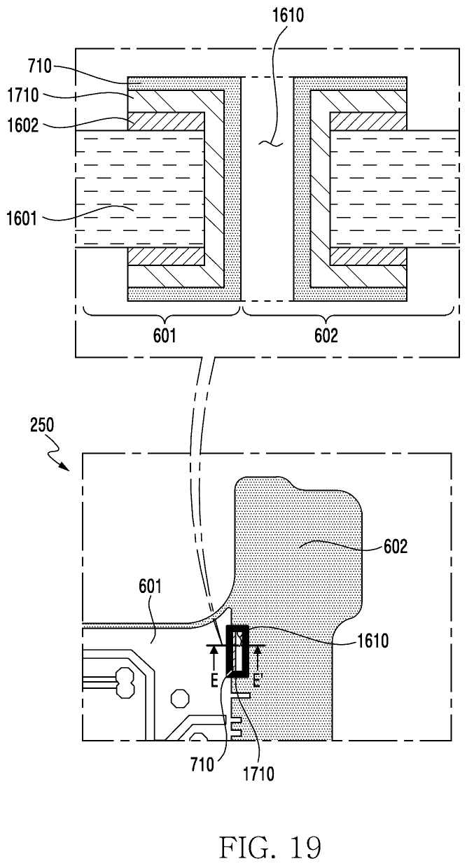

Referring to FIG. 19, a conductive material 710 may be formed by plating a metal material (e.g., gold) on a plating layer 1710. Referring to a cross-sectional view of the printed circuit board 250 of FIG. 19 cut along E-E′ line, the conductive material 710 may be formed by plating a metal material through the hole 1610, so the conductive material 710 may be formed on the plating layer 1710 included in a first PCB portion 601 and a second PCB portion 602 around the hole 1610.

Referring again to FIG. 15, in a process 1507, the opening 620 may be formed by machining the hole 1610..

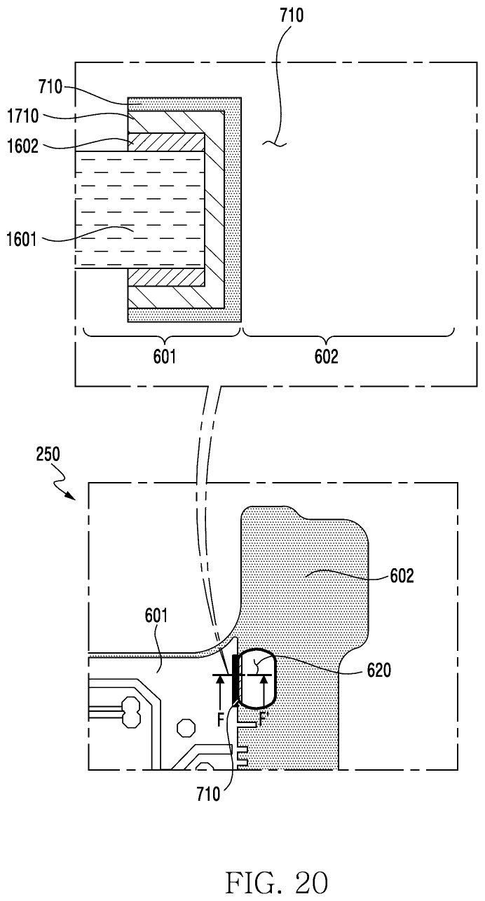

Referring to FIG. 20, an opening 620 may be formed by drilling a region around the hole 1610 of FIG. 19. Referring to a cross-sectional view of the printed circuit board 250 of FIG. 20 cut along line F-F′, the opening 620 may be formed by drilling the second PCB portion 602. A conductive material 710 exposed through the opening 620 may be electrically connected to a conductive layer 1602 in the first PCB portion 601 through a plating layer 1710.

The technical problems to be achieved in this document are not limited to those described above, and other technical problems not mentioned herein will be clearly understood by those having ordinary knowledge in the art to which the present disclosure belongs.

An electronic device 101 is disclosed. The electronic device 101 may comprise an antenna radiator 420. The electronic device 101 may comprise a printed circuit board (PCB) 251 or 252. The printed circuit board 251 or 252 may comprise a first PCB portion 601 including a plurality of layers. The plurality of layers of the first PCB portion 601 may include at least one ground layer 814 electrically connected to a ground of the electronic device 101. The printed circuit board 251 or 252 may comprise a second PCB portion 602, disposed alongside the first PCB portion 601, and including a plurality of layers. The second PCB portion may be electrically insulated from the at least one ground layer of the first PCB portion 601. The printed circuit board 251 or 252 may comprise an opening 621 defined by both a lateral side of an edge portion of the first PCB portion 601 and a lateral side of an edge portion of the second PCB portion 602. The printed circuit board 251 or 252 may comprise a conductive material 711, plated on the lateral side of the edge portion of the first PCB portion, and electrically connected to the at least one ground layer of the first PCB portion 601. The electronic device 101 may comprise an antenna contact 610, electrically connected to the antenna radiator 420, and mounted on the second PCB portion 602. The electronic device 101 may comprise impedance circuitry 430, mounted on a region of the first PCB portion 601 that comprises at least a portion of the edge portion of the first PCB portion 601, and electrically connected to the antenna contact 610. The impedance circuitry 430 may be also electrically connected to the at least one ground layer 814 of the first PCB portion 601 through the conductive material 711.

According to an embodiment, a through-via electrically connected to the impedance circuitry 430 is omitted from the first PCB portion 601.

According to an embodiment, the conductive material 711 may be configured to provide a portion (P) of a return path from the impedance circuitry 430 to the at least one ground layer 814 of the first PCB portion 601.

According to an embodiment, the impedance circuitry 430 may be disposed adjacent to the second PCB portion 602 of the PCB 251 or 252.

According to an embodiment, the electronic device 101 may further comprise a bracket 243, supporting the PCB 251 or 252, corresponding to the ground of the electronic device 101. The at least one ground layer 814 of the first PCB portion 601 may be disposed on a surface of the bracket 243.

According to an embodiment, the surface of the bracket 243 faces a rear side of the electronic device.

According to an embodiment, the electronic device 101 may further comprise a conductive connecting part 830 electrically connected to the surface of the bracket 243 and the at least one ground layer 814, respectively.

According to an embodiment, a length of a portion (P) of the return path from the impedance circuitry 430 to the at least one ground layer 814 of the first PCB portion 601 may correspond to a thickness of the PCB 251 or 252.

According to an embodiment, the electronic device 101 further may comprise a frame 218, defining at least portion of a periphery of the electronic device, including conductive portions 511 and 512 electrically connected to the antenna contact 610. The antenna radiator 420 may correspond to the conductive portions 511 and 512 of the frame 218.

According to an embodiment, the first PCB portion 601 may correspond to a fill region and the second PCB portion 602 may correspond to a fill-cut region.

According to an embodiment, the conductive material 711 may be plated on the lateral side of the edge portion of the first PCB portion 601, among the lateral side of the edge portion of the first PCB portion 601 and the lateral side of the edge portion of the second PCB portion 602.

According to an embodiment, the PCB 251 or 252 may further comprise another opening 622 defined by both a lateral side of another edge portion of the first PCB portion 601 and a lateral side of another edge portion of the second PCB portion 602, and another conductive material 711, plated on the lateral side of the other edge portion of the first PFB portion, electrically connected to the at least one ground layer of the first PCB portion 601.

According to an embodiment, the PCB 251 or 252 may include electrical wire 811 (e.g., a conductive layer), disposed in the first PCB portion 601, adjacent to the opening 621, and electrically connected to an electronic component mounted on the first PCB portion 601.

According to an embodiment, the lateral side of the edge portion of the first PCB portion 601 or the lateral side of the edge portion of the second PCB portion 602, defining the opening 621, may include an inclined portion.

According to an embodiment, the electronic device 101 may further comprise another PCB 252 or 251 on which wireless communication circuitry 192 is disposed. The electronic device 101 may further comprise a flexible PCB 410 electrically connecting the PCB 251 or 252 and the other PCB 252 or 251.

An electronic device 101 is disclosed. The electronic device 101 may comprise wireless communication circuitry 192. The electronic device 101 may comprise an antenna radiator 420 configured to transmit or receive radio frequency (RF) signals. The electronic device 101 may comprise a PCB 251 or 252 configured to electrically connect the wireless communication circuitry 192 and the antenna radiator 420. The electronic device 101 may comprise a bracket 243, supporting the PCB 251 or 252, and configured to function as a ground of the electronic device 101. The PCB 251 or 252 may include a first PCB portion 601 including at least one ground layer 814 electrically connected to the bracket 243, a second PCB portion 602, disposed alongside the first PCB portion 601, electrically insulated from the at least one ground layer 814 of the first PCB portion 601, on which an antenna contact 610 electrically connected to the antenna radiator is disposed, an opening 621 defined by both a lateral side of an edge portion of the first PCB portion 601 and a lateral side of an edge portion of the second PCB portion 602, and a conductive material 711, plated on the lateral side of the edge portion of the first PCB portion 601, electrically connected to the at least one ground layer 814 of the first PCB portion 601. A thickness of the conductive material 711 may substantially correspond to a thickness of the first PCB portion 601 of the PCB 251 or 252.

According to an embodiment, the electronic device 101 may further comprise impedance circuitry 430, mounted on a region of the first PCB portion 601 that comprises at least a portion of the edge portion of the first PCB portion 601, electrically connected to the antenna contact 610. The impedance circuitry 430 may be also electrically connected to the at least one ground layer 814 of the first PCB portion 601 through the conductive material 711.

According to an embodiment, the conductive material 711 may be configured to provide a portion (P) of a return path from the impedance circuitry 430 to the at least one ground layer 814.

According to an embodiment, a through-via electrically connected to the impedance circuitry 430 may be omitted from the first PCB portion 601.

According to an embodiment, the electronic device 101 may further comprise a frame 218, defining at least portion of a periphery of the electronic device 101, laterally surrounding the bracket 243. The frame 218 may include one or more conductive portions 510 corresponding to the antenna radiator 420.

The effects that can be obtained from the present disclosure are not limited to those described above, and any other effects not mentioned herein will be clearly understood by those having ordinary knowledge in the art to which the present disclosure belongs.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

No claim element is to be construed under the provisions of 35 U.S.C. § 112, sixth paragraph, unless the element is expressly recited using the phrase “means for” or “means.”

What is claimed is:

1. An electronic device comprising:
an antenna radiator;
a printed circuit board (PCB) including:
a first PCB portion including a plurality of layers, wherein the plurality of layers of the first PCB portion include at least one ground layer electrically connected to a ground of the electronic device,
a second PCB portion, disposed alongside the first PCB portion, including a plurality of layers, wherein the second PCB portion is electrically insulated from the at least one ground layer of the first PCB portion,
an opening defined by both a lateral side of an edge portion of the first PCB portion and a lateral side of an edge portion of the second PCB portion, and
a conductive material, plated on the lateral side of the edge portion of the first PCB portion, electrically connected to the at least one ground layer of the first PCB portion;
an antenna contact, electrically connected to the antenna radiator, mounted on the second PCB portion; and
impedance circuitry, mounted on a region of the first PCB portion comprising at least a portion of the first PCB portion, electrically connected to the antenna contact,
wherein the impedance circuitry is electrically connected to the at least one ground layer of the first PCB portion through the conductive material.

2. The electronic device of claim 1, wherein a through-via electrically connected to the impedance circuitry is omitted from the first PCB portion.

3. The electronic device of claim 1,
wherein the conductive material is configured to provide a portion of a return path from the impedance circuitry to the at least one ground layer of the first PCB portion.

4. The electronic device of claim 1,
wherein the impedance circuitry is disposed adjacent to the second PCB portion of the PCB.

5. The electronic device of claim 1, further comprising a bracket, supporting the PCB, corresponding to the ground of the electronic device,
wherein the at least one ground layer of the first PCB portion is disposed on a surface of the bracket

6. The electronic device of claim 5,
wherein the surface of the bracket faces a rear side of the electronic device.

7. The electronic device of claim 5, further comprising a conductive connecting part electrically connecting the surface of the bracket and the at least one ground layer respectively.

8. The electronic device of claim 1,
wherein a length of a portion of the return path from the impedance circuitry to the at least one ground layer of the first PCB portion corresponds to a thickness of the PCB.

9. The electronic device of claim 1, further comprising a frame, defining at least portion of a periphery of the electronic device, including conductive portion electrically connected to the antenna contact,
wherein the antenna radiator corresponds to the conductive portion of the frame.

10. The electronic device of claim 1,
wherein the first PCB portion corresponds to a fill region, and
wherein the second PCB portion corresponds to a fill-cut region.

11. The electronic device of claim 1,
wherein the conductive material is plated on the lateral side of the edge portion of the first PCB portion.

12. The electronic device of claim 1,
wherein the PCB includes:
another opening defined by both a lateral side of another edge portion of the first PCB portion and a lateral side of another edge portion of the second PCB portion, and
another conductive material, plated on the lateral side of the other edge portion of the first PCB portion, electrically connected to the at least one ground layer of the first PCB portion.

13. The electronic device of claim 1,
wherein the PCB includes an electrical wire, disposed in the first PCB portion, adjacent to the opening, and electrically connected to an electronic component mounted on the first PCB portion.

14. The electronic device of claim 1,
wherein the lateral side of the edge portion of the first PCB portion and/or the lateral side of the edge portion of the second PCB portion, defining the opening, includes an inclined portion.

15. The electronic device of claim 1, further comprising:
another PCB on which wireless communication circuitry is disposed; and
a flexible PCB electrically connecting the PCB and the other PCB.

16. An electronic device comprising:
wireless communication circuitry;
an antenna radiator configured to transmit or receive radio frequency (RF) signals;
a PCB configured to electrically connect the wireless communication circuitry and the antenna radiator; and
a bracket, supporting the PCB, configured to function as a ground of the electronic device,
wherein the PCB includes:
a first PCB portion including at least one ground layer electrically connected to the bracket,
a second PCB portion, disposed alongside the first PCB portion, electrically insulated from the at least one ground layer of the first PCB, an antenna contact electrically connected to the antenna radiator disposed on the second PCB portion,
an opening defined by both a lateral side of an edge portion of the first PCB portion and a lateral side of an edge portion of the second PCB portion, and
a conductive material, plated on the lateral side of the edge portion of the first PCB portion, electrically connected to the at least one ground layer of the first PCB portion,
wherein a thickness of the conductive material corresponds a thickness of the first PCB portion of the PCB.

17. The electronic device of claim 16, further comprising impedance circuitry, mounted on a region of the first PCB portion that comprises a portion of the edge portion of the first PCB portion, electrically connected to the antenna contact,
wherein the impedance circuitry is also electrically connected to the layer of the first PCB portion through the conductive material.

18. The electronic device of claim 17,
wherein the conductive material configured to provide a portion of a return path from the impedance circuitry to the at least one ground layer of the first PCB portion.

19. The electronic device of claim 17, wherein a through via electrically connected to the impedance circuitry is omitted from the first PCB portion.

20. The electronic device of claim 16, further comprising a frame, defining at least portion of a periphery of the electronic device, laterally surrounding the bracket,
wherein the frame includes one or more conductive portion corresponding to the antenna radiator.
